(19) United States
(12) Patent Application Publication
(10) Pub. No.: US 2012/0170162 A1
(43) Pub. Date: Jul. 5, 2012

(54) SEMICONDUCTOR PACKAGE AND FABRICATION METHOD THEREOF

(75) Inventors: Hao-Ju Fang, Taichung (TW); Hsin-Lung Chung, Taichung (TW); Kuang-Neng Chung, Taichung (TW); Chien-Cheng Lin, Taichung (TW); Heng-Cheng Chu, Taichung (TW)

(73) Assignee: SILICONWARE PRECISION INDUSTRIES CO., LTD., Taichung (TW)

(21) Appl. No.: 13/053,559

(22) Filed: Mar. 22, 2011

(30) Foreign Application Priority Data
Jan. 5, 2011 (TW) 100100262

(51) Int. Cl. H02H 9/04; H01L 21/56

(52) U.S. Cl. 361/56; 438/124; 257/E21.502

(57) ABSTRACT

A semiconductor package is provided, which includes a substrate unit having conductive pads and ESD protection pads formed on a bottom surface thereof; an encapsulant covering a top surface of the substrate unit; and a metal layer disposed on a top surface of the encapsulant and having connecting extensions formed on side surfaces of the substrate unit and the encapsulant for electrically connecting the ESD protection pads, wherein portions of the side surfaces of the substrate unit corresponding in position to the conductive pads are exposed from the metal layer so as to ensure that solder bumps subsequently formed to connect the conductive pads of the semiconductor package to a circuit board are not in contact with the metal layer, thereby effectively avoiding the risk of short circuits.

### BACKGROUND OF THE INVENTION

1. Field of the Invention

The present invention relates to semiconductor packages and fabrication methods thereof, and more particularly, to a semiconductor package capable of preventing short circuit and electromagnetic interference (EMI) and a fabrication method thereof.

2. Description of Related Art

Generally, to achieve an EMI shielding effect, a semiconductor package has a metal layer plated on a top surface and side surfaces thereof and the metal layer on the side surfaces of the semiconductor package is further connected to a ground plane of a circuit board. However, in such a semiconductor package, circuits need to be formed on a side surface of the semiconductor package to achieve the electrical connection between the metal layer and the ground plane, thereby complicating the fabrication process. To overcome the drawback, the metal layer is selectively plated on the bottom surface, the top surface and the side surfaces of a semiconductor package for being connected to a circuit board. FIGS. 1A to 1C show a fabrication method of such a conventional semiconductor package.

Referring to FIG. 1A, a prepared package 1 is provided, which comprises a substrate unit 10 and an encapsulant 11. The substrate unit 10 has a first surface 10a with a plurality of conductive pads 100 and electrostatic discharging (ESD) protection pads 101 and a second surface 10b opposite to the first surface 10a and covered by the encapsulant 11.

Referring to FIGS. 1B and 1C, a metal layer 12 is formed on all side surfaces 10c of the substrate unit 10 and all exposed surfaces of the encapsulant 11.

Referring to FIG. 1C, the package is disposed on a circuit board 5, wherein the ESD protection pads 101 and the conductive pads 100 are connected to the circuit board 5 through a plurality of solder bumps 4. However, during soldering, solder bridges can easily occur between the solder bumps 4 on the conductive pads 100 at the periphery of the substrate unit 10 and the metal layer 12 on the side surfaces 10c of the substrate unit 10, thereby causing short circuits between the conductive pads 100 and the metal layer 12. Particularly, if the metal layer 12 is a solderable material, short circuits caused by solder bridges between the conductive pads 100 and the metal layer 12 become more severe.

Therefore, there is a need to provide a semiconductor package and a fabrication method thereof so as to overcome the above-described drawbacks.

### SUMMARY OF THE INVENTION

Accordingly, the present invention provides a semiconductor package, which comprises: a substrate unit having a first surface with a plurality of conductive pads and a plurality of ESD protection pads and a second surface opposite to the first surface; an encapsulant formed on the substrate unit for covering the second surface of the substrate unit; and a metal layer formed on a top surface of the encapsulant and having a plurality of connecting extensions formed on side surfaces of the substrate unit and the encapsulant for electrically connecting the ESD protection pads, wherein portions of the side surfaces of the substrate unit corresponding in position to the conductive pads are exposed from the metal layer.

The present invention further provides a fabrication method of a semiconductor package, which comprises the steps of: providing a substrate unit having a first surface with a plurality of conductive pads and a plurality of ESD protection pads and a second surface opposite to the first surface; covering the second surface of the substrate unit with an encapsulant; and forming a metal layer on a top surface of the encapsulant, wherein the metal layer has a plurality of connecting extensions formed on side surfaces of the substrate unit and the encapsulant for electrically connecting to the ESD protection pads, and portions of the side surfaces of the substrate unit corresponding in position to the conductive pads are exposed from the metal layer.

Before forming the metal layer, the method can further comprise the step of providing a receiving member having a bottom portion, side walls and recesses formed in the side walls and the bottom portion, wherein the first surface of the substrate unit is disposed on the bottom portion of the receiving member such that the conductive pads are covered by the bottom portion and the side walls abut against the side surfaces of the substrate unit while the ESD protection pads are exposed through the recesses so as to be electrically connected to the connecting portions subsequently formed on the side surfaces of the substrate unit and the encapsulant; and after forming the metal layer, the method can further comprise the step of removing the receiving member.

Further, the recesses can allow exposed surfaces of the encapsulant and the receiving member to be spaced from each other so as to allow the ESD protection pads to be connected to the connecting extensions subsequently formed on the exposed surfaces of the encapsulant.

In the above-described semiconductor package and fabrication method thereof, the connecting extensions can extend to and cover the ESD protection pads. Further, each of the connecting extensions on a side surface of the substrate unit can have a width less than the sum of the width of the corresponding ESD protection pad and the distance between the corresponding ESD protection pad and one of the conductive pads adjacent to the corresponding ESD protection pad.

In the above-described semiconductor package and fabrication method thereof, the first surface of the substrate unit can be rectangular, the ESD protection pads are disposed on corners of the first surface of the substrate unit, and the connecting extensions are formed around corners of the substrate unit and extend to the first surface of the substrate unit around the ESD protection pads.

In the above-described semiconductor package and fabrication method thereof, the ESD protection pads can be disposed on edges of the first surface of the substrate unit.

In the above-described semiconductor package and fabrication method thereof, the metal layer can be formed on all exposed surfaces of the encapsulant.

According to the present invention, since the metal layer is not formed on the portions of the side surfaces of the substrate unit corresponding in position to the conductive pads, when solder bumps are formed to electrically connect the conductive pads to a circuit board, the solder bumps will not be in contact with the metal layer, thereby effectively avoiding the risk of short circuits between the conductive pads and the metal layer.

Even if the metal layer is made of a material the same as the solder bumps, since the solder bumps are prevented from being in contact with the metal layer on the side surfaces of the substrate unit, the risk of solder bridges is avoided.

### BRIEF DESCRIPTION OF DRAWINGS

FIGS. 1A and 1B are schematic views of a conventional semiconductor package, wherein FIG. 1A is a cross-sectional view, and FIG. 1B is a bottom view;

FIG. 1C is a cross-sectional view showing application of the conventional semiconductor package, wherein the cross-sectional view of the semiconductor package is taken along a line A-A of FIG. 1B;

FIGS. 2A to 2C are schematic views showing a fabrication method of a semiconductor package according to an embodiment of the present invention, wherein FIGS. 2A and 2C are perspective views, respectively, FIGS. 2A′ and 2C′ are cross-sectional views of FIGS. 2A and 2C, respectively, FIG. 2B′ is a cross-sectional view taken along a line B-B of FIG. 2B, FIG. 2B″ is a cross-sectional view taken along a line C-C of FIG. 2B, and FIG. 2C″ is a local side view of FIG. 2C; and

FIG. 3 is a perspective view of a semiconductor package according to another embodiment of the present invention.

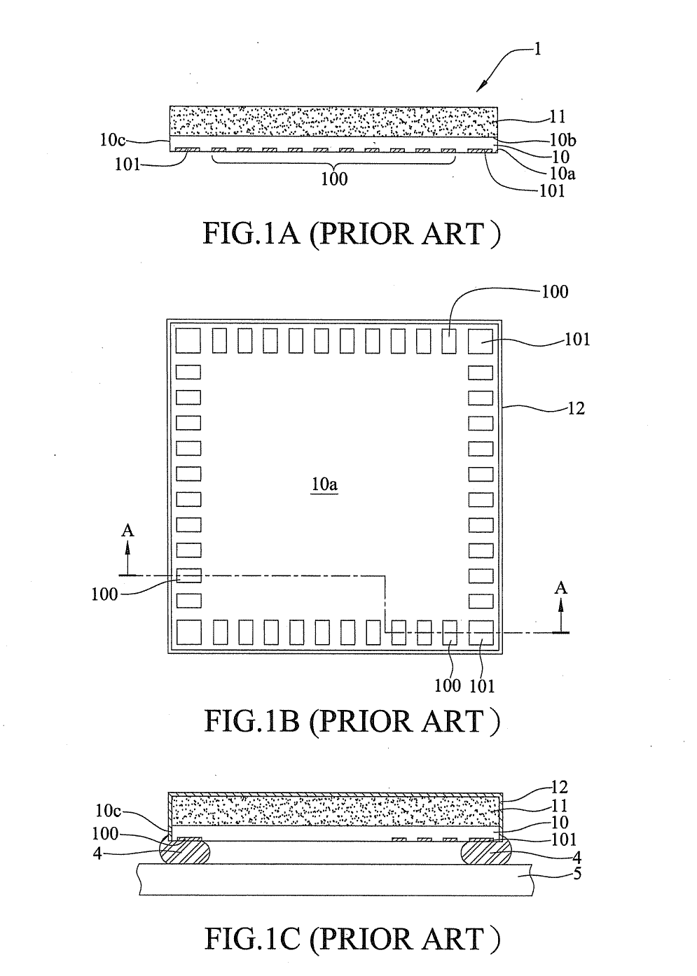

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “one”, “top”, “above”, etc. are merely for illustrative purpose and should not be construed to limit the scope of the present invention.

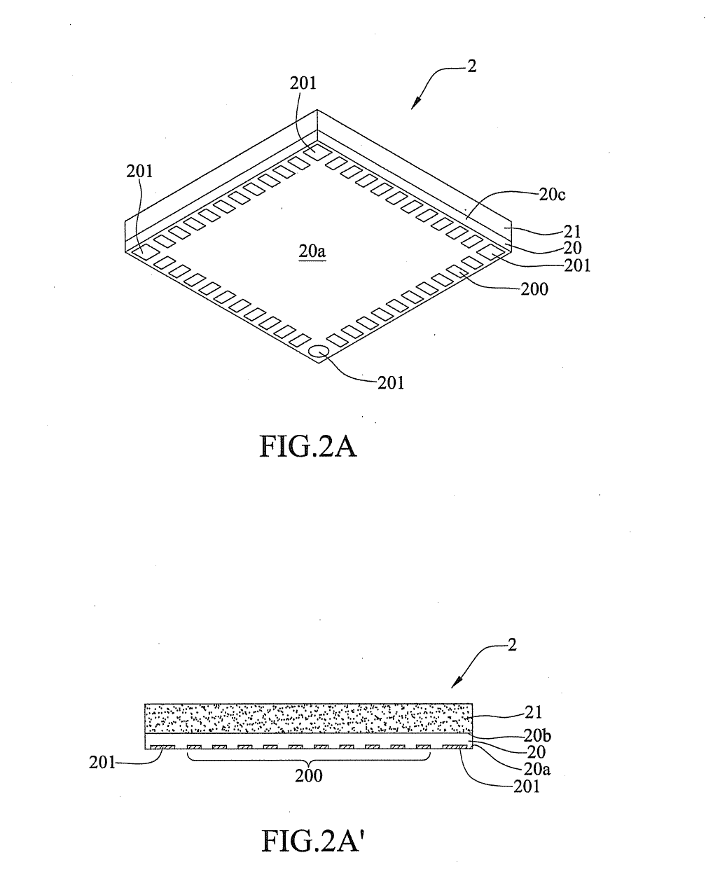

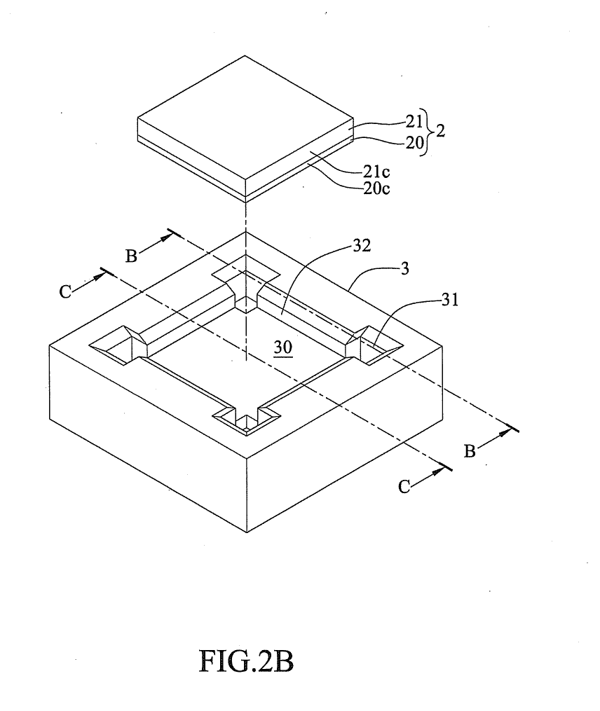

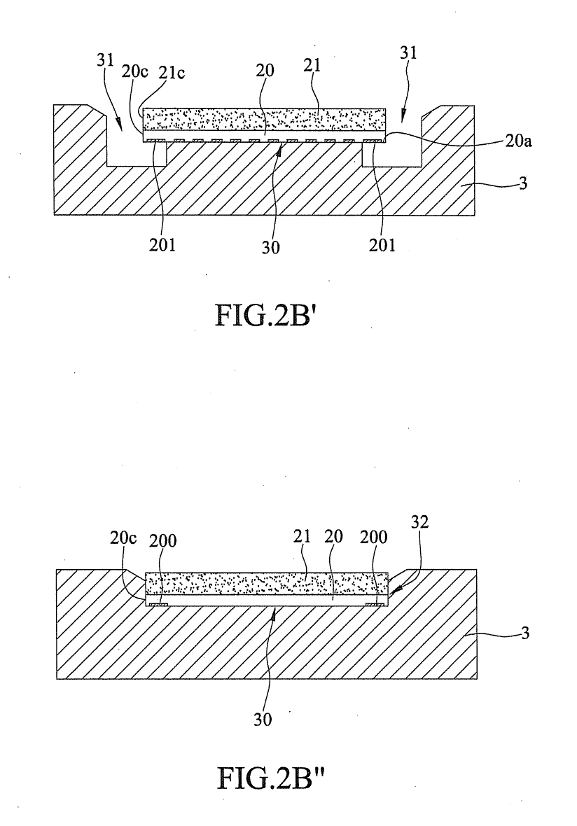

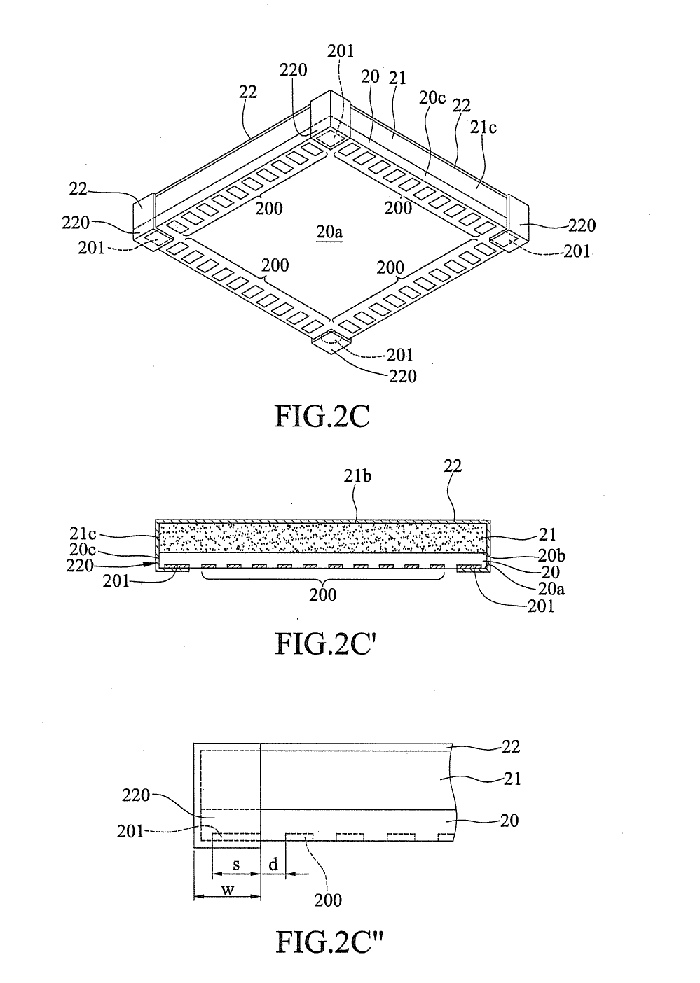

FIGS. 2A to 2C show a fabrication method of a semiconductor package according to an embodiment of the present invention, wherein FIGS. 2A and 2C are perspective views, respectively, FIGS. 2A′ and 2C′ are cross-sectional views of FIGS. 2A and 2C, respectively, FIG. 2B′ is a cross-sectional view taken along a line B-B of FIG. 2B, FIG. 2B″ is a cross-sectional view taken along a line C-C of FIG. 2B, and FIG. 2C″ is a local side view of FIG. 2C.

Referring to FIGS. 2A and 2A′, a prepared package 2 is provided, which comprises a substrate unit 20 and an encapsulant 21 formed on the substrate unit 20. The substrate unit 20 has a first surface 20a with a plurality of conductive pads 200 and a plurality of ESD protection pads 201 and a second surface 20b opposite to the first surface 20a.

In the present embodiment, at least a semiconductor chip (not shown) is disposed on the second surface 20b of the substrate unit 20, and the semiconductor chip and the second surface 20b of the substrate unit 20 are covered by the encapsulant 21.

Further, the semiconductor chip can be electrically connected to conductive pads (not shown) on the second surface 20b of the substrate unit 20 through bonding wires. Alternatively, the semiconductor chip can be flip-chip electrically connected to the conductive pads (not shown) on the second surface 20b of the substrate unit 20 through solder bumps.

Furthermore, the first surface 20a of the substrate unit 20 has a rectangular shape. The ESD protection pads 201 are formed on corners of the first surface 20a of the substrate unit 20 and not flush with side surfaces 20c of the substrate unit 20. In other embodiments, the ESD protection pads 201 can be formed on edges of the first surface 20a of the substrate unit 20.

Referring to FIGS. 2B, 2B′ and 2B″, a receiving member 3 is provided, which comprises a bottom portion 30, side walls 32, and recesses 31 formed in the side walls 32 and the bottom portion 30.

The first surface 20a of the substrate unit 20 is disposed on the bottom portion 30 such that the conductive pads 200 are covered by the bottom portion 30 while the ESD protection pads 201 are exposed through the recesses 31 so as to be electrically connected to connecting extensions subsequently formed on side surfaces 20c, 21c of the prepared package 2. Further, the side walls abut against the side surfaces 20c of the substrate unit 20, as shown in FIG. 2B″. In addition, the recesses 31 allow portions of the side surfaces 21c of the encapsulant 21 to be spaced from the receiving member 3 so as to allow the ESD protection pads 201 to be electrically connected to connecting extensions subsequently formed on the exposed surfaces of the encapsulant 21.

That is, the ESD protection pads 201, and the first surface 20a as well as the side surfaces 20c, 21c of the substrate unit 20 and the encapsulant 21 around the ESD protection pads 201 are spaced from the receiving member 3 through the recesses 31, as shown in FIG. 2B′.

Referring to FIGS. 2C, 2C′ and 2C″, a metal layer 22 is formed on a top surface 21b of the encapsulant 21 by electroless plating, wherein portions of the side surfaces 20c of the substrate unit 20 corresponding in position to the conductive pads 200 are exposed from the metal layer 22. Then, the receiving member 3 is removed.

In particular, the metal layer 22 has a plurality of connecting extensions 220 formed around corners of the substrate unit 20 and the encapsulant 21 and extending to the first surface 20a of the substrate unit 20 around the ESD protection pads 201. Since the ESD protection pads 201 of the present embodiment are embedded in the substrate unit 20, the connecting extensions 220 further extend to the ESD protection pads 201 for electrically connecting the ESD protection pads 201.

Further, referring to FIG. 2C″, each of the connecting portions 220 on a side surface 20c of the substrate unit 20 has a width w less than the sum of the width s of the corresponding ESD protection pad 201 and the distance d between the corresponding ESD protection pad 201 and the conductive pad 200 adjacent to the corresponding ESD protection pad 201, i.e. w<s+d.

The metal layer 22 can be made of Cu, Ni, Fe, Al, stainless steel (SUS). The metal layer 22 provides an EMI shielding effect for the semiconductor package.

By using the receiving member 3, the present invention avoids formation of the metal layer 22 on the portions of the side surfaces 20c of the substrate unit 20 corresponding in position to the conductive pads 200. As such, when solder bumps are formed to connect the conductive pads 200 to a circuit board, the solder bumps will not be in contact with the metal layer 22, thereby effectively avoiding the risk of short circuits between the conductive pads 200 and the metal layer 22.

Further, even if the metal layer 22 is made of a solderable material, since the solder bumps are prevented from being in contact with the metal layer 22 on the side surfaces 20c of the substrate unit 20, the risk of solder bridges is avoided.

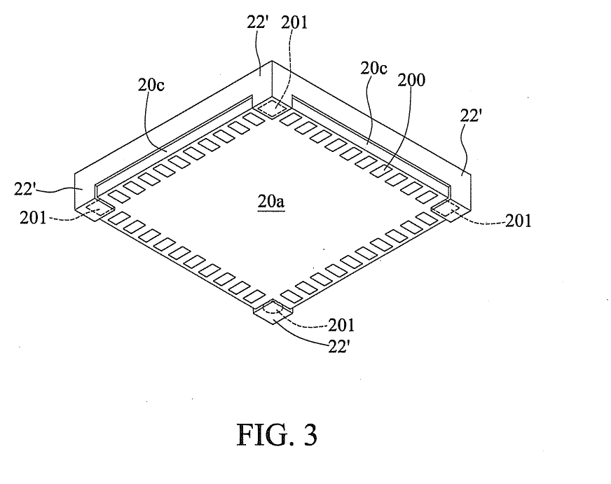

FIG. 3 shows another embodiment of the semiconductor package, wherein a metal layer 22′ is formed on the top surface 21b and all the side surfaces 21c of the encapsulant 21.

The present invention further provides a semiconductor package, which comprises: a substrate unit 20 having a first surface 20a and a second surface 20b opposite to the first surface 20a; an encapsulant 21 formed on the substrate unit 20 for covering the second surface 20b of the substrate unit 20; and a metal layer 22 formed on a top surface of the encapsulant 21.

Therein, the first surface 20a of the substrate unit 20 has a plurality of conductive pads 200 and a plurality of ESD protection pads 201, and the second surface 20b of the substrate unit 20 has at least a semiconductor chip disposed thereon. The encapsulant 21 covers the semiconductor chip and the second surface 20b of the substrate unit 20.

In the above-described substrate unit 20, the ESD protection pads 201 are formed on edges of the first surface 20a of the substrate unit 20. If the first surface 20a of the substrate unit 20 is rectangular, the ESD protection pads 201 can be formed on corners of the first surface 20a of the substrate unit 20 but are not flush with side surfaces of the substrate unit 20.

The metal layer 22 has a plurality of connecting extensions 220 formed on side surfaces 20c, 21c of the substrate unit 20 and the encapsulant 21 for electrically connecting the ESD protection pads 201, and portions of the side surfaces 20c of the substrate unit 20 corresponding in position to the conductive pads 200 are exposed from the metal layer 22. In an embodiment, the connecting extensions 220 further extend to cover the ESD protection pads 201.

Each of the connecting extensions 220 on any one of the side surfaces 20c of the substrate unit 20 has a width w less than the sum of the width s of the corresponding ESD protection pad 201 and the distance d between the corresponding ESD protection pad 201 and an adjacent conductive pad 200. Further, the connecting extensions 220 can be formed around corners of the substrate unit 20 and extend to the first surface 20a around the ESD protection pads 201.

In addition, the metal layer 22′ of FIG. 3 can be formed on all exposed surfaces of the encapsulant 21.

According to the present invention, since the metal layer is not formed on the portions of the side surfaces of the substrate unit corresponding in position to the conductive pads, when solder bumps are formed to connect the conductive pads to a circuit board, the solder bumps will not be in contact with the metal layer, thereby effectively avoiding the risk of short circuits between the conductive pads and the metal layer.

Even if the metal layer is made of a material the same as the solder bumps, since the solder bumps cannot be in contact with the metal layer on the side surfaces of the substrate unit, the risk of solder bridges is avoided.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A semiconductor package, comprising:
a substrate unit having a first surface with a plurality of conductive pads and a plurality of electrostatic discharging (ESD) protection pads and a second surface opposite to the first surface;
an encapsulant formed on the substrate unit for covering the second surface of the substrate unit; and
a metal layer provided on a top surface of the encapsulant and having a plurality of connecting extensions formed on side surfaces of the substrate unit and the encapsulant for electrically connecting the ESD protection pads, wherein portions of the side surfaces of the substrate unit corresponding in position to the conductive pads are exposed from the metal layer.

2. The package of claim 1, wherein the connecting extensions extend to cover the ESD protection pads, respectively.

3. The package of claim 1, wherein each of the connecting extensions on any one of the side surfaces of the substrate unit has a width less than a sum of a width of the corresponding ESD protection pad and a distance between the corresponding ESD protection pad and one of the conductive pads adjacent to the corresponding ESD protection pad.

4. The package of claim 1, wherein the metal layer is formed on all exposed surfaces of the encapsulant.

5. The package of claim 1, wherein the ESD protection pads are disposed on edges of the first surface of the substrate unit.

6. The package of claim 1, wherein the first surface of the substrate unit is rectangular, the ESD protection pads are formed on corners of the first surface of the substrate unit, and the connecting extensions are formed around the corners of the substrate unit and extend to the first surface of the substrate unit around the ESD protection pads.

7. A fabrication method of a semiconductor package, comprising the steps of:
providing a substrate unit having a first surface with a plurality of conductive pads and a plurality of ESD protection pads and a second surface opposite to the first surface;
covering the second surface of the substrate unit with an encapsulant; and
forming a metal layer on a top surface of the encapsulant, wherein the metal layer has a plurality of connecting extensions formed on side surfaces of the substrate unit and the encapsulant for electrically connecting the ESD protection pads, and portions of the side surfaces of the substrate unit corresponding in position to the conductive pads are exposed from the metal layer.

8. The method of claim 7, wherein the connecting extensions extend to cover the ESD protection pads, respectively.

9. The method of claim 7, wherein each of the connecting extensions on any one of the side surfaces of the substrate unit has a width less than a sum of a width of the corresponding ESD protection pad and a distance between the corresponding ESD protection pad and one of the conductive pads adjacent to the corresponding ESD protection pad.

10. The method of claim 7, wherein the metal layer is formed on all exposed surfaces of the encapsulant.

11. The method of claim 7, wherein the ESD protection pads are formed on edges of the first surface of the substrate unit.

12. The method of claim 7, wherein the first surface of the substrate unit is rectangular, the ESD protection pads are disposed on corners of the first surface of the substrate unit, and the connecting extensions are formed around the corners of the substrate unit and extend to the first surface of the substrate unit around the ESD protection pads.

13. The method of claim 7, before forming the metal layer, further comprising the step of providing a receiving member having a bottom portion, side walls and recesses formed in the side walls and the bottom portion, wherein the first surface of the substrate unit is disposed on the bottom portion of the receiving member such that the conductive pads are covered by the bottom portion and the side walls abut against the side surfaces of the substrate unit while the ESD protection pads are exposed through the recesses so as to be electrically connected to the connecting extensions subsequently formed on the side surfaces of the substrate unit and the encapsulant; and after forming the metal layer, the method further comprising the step of removing the receiving member.

14. The method of claim 13, wherein the recesses allow exposed surfaces of the encapsulant and the receiving member to be spaced from each other so as to allow the ESD protection pads to be electrically connected to the connecting extensions subsequently formed on the exposed surfaces of the encapsulant.
